(19) United States
(12) Patent Application Publication
(10) Pub. No.: US 2005/0174165 A1
(43) Pub. Date: Aug. 11, 2005

(54) Constant current source apparatus including two series depletion-type MOS transistors

(75) Inventor: Eiji Shimada, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki-shi (JP)

(21) Appl. No.: 11/049,720

(22) Filed: Feb. 4, 2005

(30) Foreign Application Priority Data
Feb. 5, 2004 (JP) 2004-029390

(51) Int. Cl. H03K 5/153

(52) U.S. Cl. 327/543

(57) ABSTRACT

In a constant current source apparatus for supplying a load current to at least one load, first and second output terminals are provided, and at least one of the first and second output terminals is capable of being connected to the load. First and second depletion-type MOS transistors are connected in series between the first and second output terminals. A source and a gate of the first depletion-type MOS transistor are connected to a gate of the second depletion-type MOS transistor.

### BACKGROUND OF THE INVENTION

1. Field of the Invention

The present invention relates to a constant current source apparatus for supplying a constant current to at least one load.

2. Description of the Related Art

A prior art constant current source apparatus is constructed by a gate-source short-circuited depletion-type metal oxide semiconductor (MOS) transistor connected between a load connected to a power supply terminal and a ground terminal, so that a load current flowing through the load is made constant (see: FIG. 5 of JP-5-13686-A). This will be explained later in detail.

In the above-described prior art constant current source apparatus, however, when a voltage applied thereto fluctuates, the load current would fluctuate due to the channel length modulation effect of the depletion-type MOS transistor.

Also, in the above-described prior art constant current source apparatus, where the voltage applied to thereto is too high, no use is made of a low drain-to-source breakdown depletion-type MOS transistor, which would increase the layout area and degrade the current characteristics.

### SUMMARY OF THE INVENTION

It is an object of the present invention to provide a constant current source apparatus capable of suppressing the fluctuation of a load current due to the channel length modulation effect.

Another object of the present invention is to provide a constant current source apparatus capable of decreasing the layout area and improving the current characteristics.

According to the present invention, in a constant current source apparatus for supplying a load current to at least one load, first and second output terminals are provided, and at least one of the first and second output terminals is capable of being connected to the load. First and second depletion-type MOS transistors are connected in series between the first and second output terminals. A source and a gate of the first depletion-type MOS transistor are connected to a gate of the second depletion-type MOS transistor.

### BRIEF DESCRIPTION OF THE DRAWINGS

The present invention will be more clearly understood from the description set forth below, as compared with the prior art, with reference to the accompanying drawings, wherein:

FIG. 1 is a circuit diagram illustrating a prior art constant current source apparatus;

FIG. 2 is a graph showing the current characteristics of the load current of FIG. 1;

FIG. 3 is a circuit diagram illustrating a first embodiment of the constant current source apparatus according to the present invention;

FIG. 4 is a graph showing the current characteristics of the first depletion-type N-channel MOS transistor of FIG. 3;

FIGS. 5A and 5B are graphs showing the current characteristics of the second depletion-type N-channel MOS transistor of FIG. 3;

FIGS. 6A and 6B are graphs showing the operating point of the constant current source apparatus of FIG. 3;

FIGS. 7A and 7B are graphs showing the special operating point of the constant current source apparatus of FIG. 3;

FIG. 8 is a circuit diagram illustrating a modification of the constant current source apparatus of FIG. 3;

FIG. 9 is a circuit diagram illustrating a second embodiment of the constant current source apparatus according to the present invention;

FIG. 10 is a circuit diagram illustrating a modification of the constant current source apparatus of FIG. 9; and

FIGS. 11 and 12 are circuit diagrams illustrating modifications of the constant current source apparatuses of FIGS. 3 and 9, respectively.

### DESCRIPTION OF THE PREFERRED EMBODIMENTS

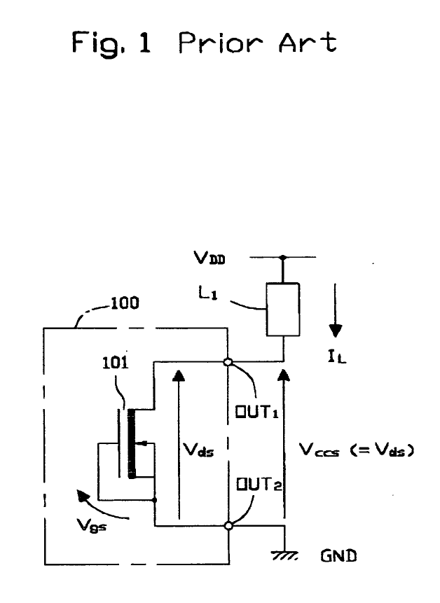

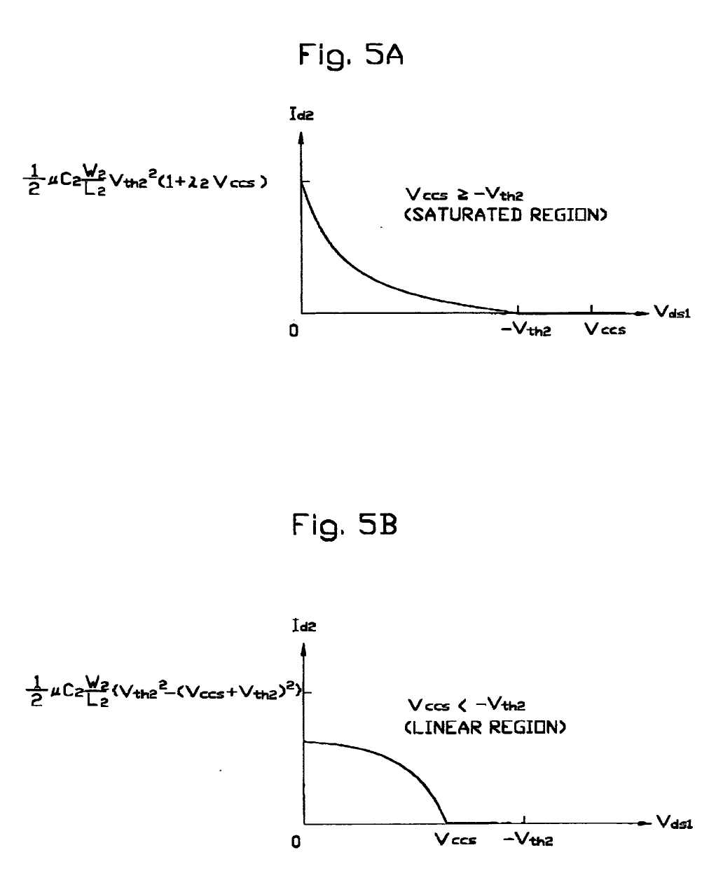

Before the description of the preferred embodiments, a prior art constant current source apparatus will be explained with reference to FIG. 1 (see: FIG. 5 of JP-5-13686-A).

In FIG. 1, a constant current source apparatus 100 has an output terminal OUT₁ connected to a load L₁ which is further connected to a power supply terminal to which a power supply voltage V_{DD} is applied, and an output terminal OUT₂ connected to a ground terminal to which a ground voltage GND is applied.

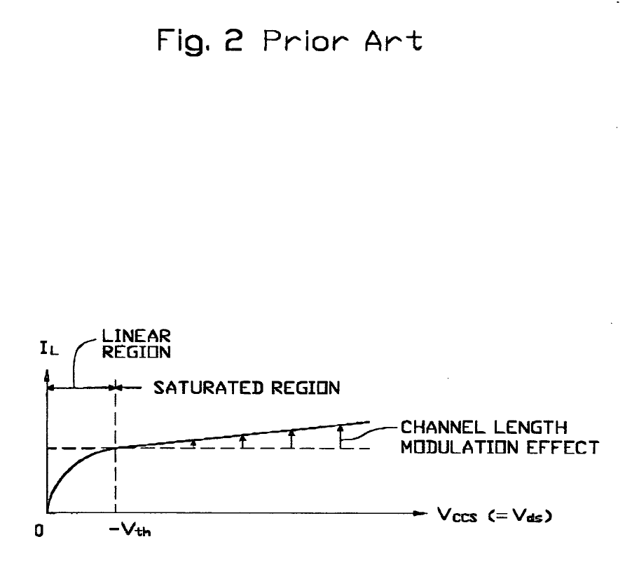

The constant current source apparatus 100 is constructed by a depletion-type R-channel MOS transistor 101 with a source connected to the ground terminal (GND), a gate connected to the source, a drain connected to the load L₁ and a back gate connected to the source. Therefore, since the gate-to-source voltage of the depletion-type N-channel MOS transistor 101 is 0V, a saturated drain current flowing therethrough, ie, a load current L₁ flowing through the load L₁ is limited in a saturated region where a voltage V_{ccs} applied to the constant current source apparatus 100, i.e., the drain-to-source voltage V_{ds} of the depletion-type N-channel KOS transistor 101 is higher than an absolute value of a threshold voltage Vₜₕ thereof, as shown in FIG. 2. Thus, a constant load current I_{L} equal to the saturated drain current of the depletion-type N-channel MOS transistor 101 flows through the load L₁ under a condition that V_{ccs} (=V_{ds})≧Vₜₕ.

Note that, the larger the voltage V_{CCS}, the higher the drain-to-source breakdown voltage of the depletion-type N-channel MOS transistor 101. Also, the higher this drain-to-source breakdown voltage, the larger the threshold voltage Vₜₕ.

In the constant current source apparatus 100 of FIG. 1, however, when the voltage V_{CCS} fluctuates, the load current I_{L} would fluctuate due to the channel length modulation effect of the depletion-type N-channel NOS transistor 101. That is, as shown in FIG. 2, when the voltage V_{CCS} is increased, the drain-to-source voltage of the depletion-type N-channel MOS transistor 101 is directly increased, so that the load current I_{L} would be increased by the channel length modulation effect.

Also, in the constant current source apparatus 100 of FIG. 1, where the voltage V_{CCS} is too high, no use is made of a low drain-to-source breakdown depletion-type MOS transistor, which would increase the layout area and degrade the current characteristics, since a high drain-to-source breakdown depletion-type MOS transistor generally has a layger layout area and degraded current characteristics such as a degraded constant current characteristic, a degraded temperature dependency and a degraded diffusion fluctuation than a low drain-to-source breakdown-type MOS transistor.

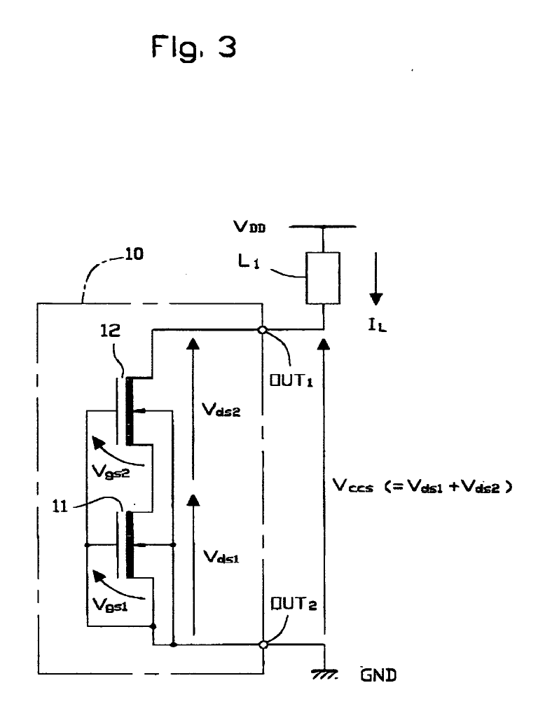

In FIG. 3, which illustrates a first embodiment of the constant current source apparatus according to the present invention, a constant current source apparatus 10 is constructed by depletion-type MOS N-channel transistors 11 and 12 connected in series between the output terminals OUT₁ and OUT₂. In this case, a source and a gate of the depletion-type N-channel MOS transistor 11 is connected to a source of the depletion-type N-channel MOS transistor 12. Also, back gates of the depletion-type N-channel MOS transistors 11 and 12 are directly grounded.

In FIG. 3,
V_{ds1}=−V_{gsZ} (1)
where V_{ds1} is a drain-to-source voltage of the depletion-type N-channel MOS transistor 11; and

V_{gsZ} is a gate-to-source voltage of the depletion-type N-channel MOS transistor 12.

In FIG. 3, a voltage V_{ccs} is applied to the constant current source apparatus 10, and a load current I_{L} flows through the load L₁.

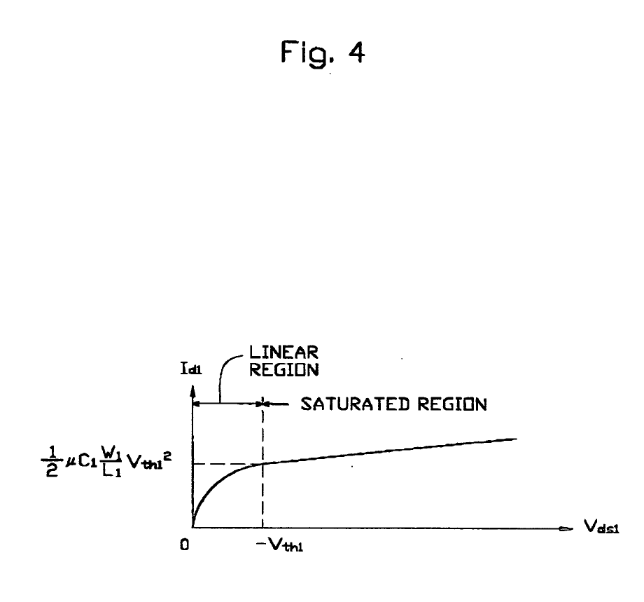

As shown in FIG. 4, as the drain-to-source voltage V_{ds1} of the depletion-type N-channel MOS transistor 11 is increased, the drain current I_{d1} of the depletion-type N-channel MOS transistor 11 is gradually increased in a linear region where V_{ds1} is between 0 and −Vₜₕ₁ where Vₜₕ₁ is a negative threshold voltage of the depletion-type N-channel MOS transistor 11. Also, in a saturated region where the drain-to-source voltage V_{ds1} is higher than −Vₜₕ₁, the drain current I_{d1} is saturated but increased a little by the channel length modulation effect.

On the other hand, as shown in FIGS. 5A and 5B, as the drain-to-source voltage V_{ds2} of the depletion-type N-channel MOS transistor 12 is increased, the drain current I_{d2} of the depletion-type N-channel MOS transistor 12 is gradually decreased. In more detail, as shown in FIG. 5A, when V_{CCS}≧−V_{thZ} (saturated region), the drain current I_{d2} is gradually decreased between V_{ds2}=0 and V_{ds2}=−Vₜₕ₂ where Vₜₕ₂ is a negative threshold voltage of the depletion-type N-channel MOS transistor 12, and when the drain-to-source voltage V_{dsZ} is higher than −Vₜₕ₂, the drain current I_{d2} is 0. Also, as shown in FIG. 5B, when V_{CCS}<−Vₜₕ₂ (linear region), the drain current I_{dz} is gradually decreased between V_{ds2}=0 and V_{ds2}=V_{CCS}, and when the drain-to-source voltage V_{ds2} is higher than V_{CCS}, the drain current I_{dZ} is 0.

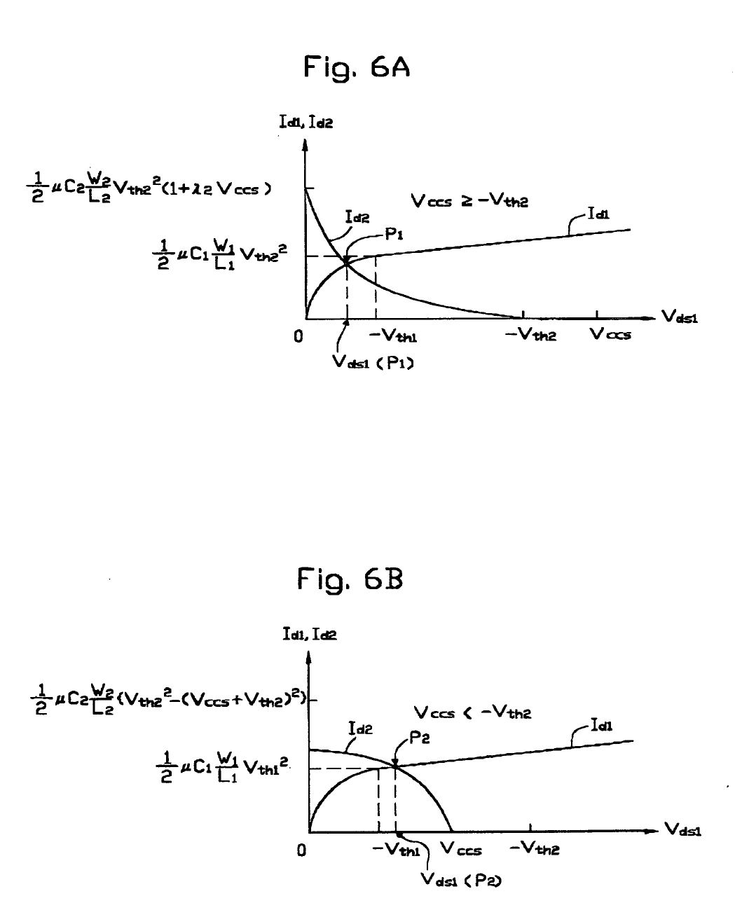

Therefore, when combining the current characteristics of FIG. 4 with the current characteristics of FIGS. 5A and 5B, only one operating point P₁ or P₂, where the drain current I_{d1} of the depletion-type N-channel MOS transistor 11 coincides with the drain current I_{d2} of the depletion-type N-channel MOS transistor 12, always exists, as shown in FIGS. 6A and 6B. In this case, the drain-to-source voltage V_{ds1} (P₁) or V_{ds1} (P₂) at the operating point P₁ or P₂ is smaller than −Vₜₕ₂, i.e.,
V_{ds1}(P₁)<−Vₜₕ₂ (2)
V_{ds1}(P₂)<Vₜₕ₂ (3)

Thus, the drain-to-source voltage V_{ds1} of the depletion-type N-channel MOS transistor 11 at the operating points P₁ and P₂ is smaller than −Vₜₕ₂.

Therefore, the drain-to-source breakdown voltage of the depletion-type N-channel MOS transistor 11 can be small; In this case, the minimum value of this breakdown voltage is −Vₜₕ₂, i.e., this breakdown voltage is not smaller than −V_{thz}. As a result, a low drain-to-source breakdown voltage depletion-type MOS transistor can be used for the depletion-type N-channel MOS transistor 11. On the other hand, the minimum value of the drain-to-source breakdown voltage of the depletion-type N-channel MOS transistor 12 is V_{DD}, i.e., this breakdown voltage is not smaller than V_{DD}. As a result, a high drain-to-source breakdown voltage depletion-type MOS transistor is used for the depletion-type N-channel MOS transistor 12. Note that low breakdown voltage MOS transistors are generally excellent in temperature dependency of current, between-element fluctuation as compared with high breakdown voltage MOS transistors.

The operating point P₁ or P₂ where is unambiguously determined set forth below with reference to FIGS. 4, 5A, 5B, 6A and 6B.

As shown in FIG. 4, the drain current I_{d1} of the depletion-type N-channel MOS transistor 11 is represented by
I_{d1}=μC₁−(W₁/L₁)−{(V_{gs1}−Vₜₕ₁)−V_{ds1}−(1½)−V_{ds1}²}for V_{ds1}≦V_{gs1}−Vₜₕ₁ (linear region) (4)
I_{d1}=(½)−μC₁−(W₁/L₁)−(V_{gs1}−Vₜₕᵢ)²−(1+λ₁V_{ds1}) for V_{ds1}>V_{gs1}−Vₜₕ₁ (saturated region) (5)
C₁ is a gate capacitance per unit area;
W₁ is a gate width;
L₁ is a gate length;
V_{gs1} is a gate-to-source voltage;
Vₜₕ₁ (<0) is a threshold voltage;
λ₁ (>0) is a channel length modulation factor; and
V_{ds1} is a drain-to-source voltage.
Since V_{gs1}=0, the formulae (4) and (5) are replaced by
   I_{d1}=(½)−μC₁−(W₁/L₁)−{Vₜₕ₁²−(V_{ds1}+Vₜₕ₁)²}for V_{ds1}≦V_{gs1}Vₜₕ₁ (linear region) (6)
   I_{d1}=(½)−μC₁−(W₁/L₁)−Vₜₕ₁²(1+λ₁V_{ds1}) for V_{ds1}>V_{gs1}−Vₜₕ₁ (saturated region) (7)

Also, in FIG. 5A, since V_{ccs}≧−V_{thZ},

$$\begin{matrix}{V}_{ds2} = {V}_{ccs} - {V}_{ds1} \\ = {V}_{ccs} + {V}_{gs2} \\ ≧ {V}_{gs2} - {V}_{th2}\end{matrix}$$

Thus, the depletion-type N-channel MOS transistor 12 is operated in a saturated region. Therefore, the drain current I_{d2} of the depletion-type N-channel MOS transistor 12 is represented by
I_{d2}=(½)−μC₂(W₂/L₂)−(V_{gs2}−Vₜₕ₂)²(1+λ_{Z}V_{ds2}) for V_{ds2}>Vₜₕ₂ (saturated region) (8)
C₂ is a gate capacitance per unit area;
W_{Z} is a gate width;
L_{Z} is a gate length;
V_{gs2} is a gate-to-source voltage;
Vₜₕ₂ (<0) is a threshold voltage;
λ_{Z} (>0) is a channel length modulation factor; and

V_{ds2} is a drain-to-source voltage.

Further, in FIG. 5B, since V_{ccs}<−Vₜₕ₂,

$$\begin{matrix}{I}_{d2} = {V}_{ccs} - {V}_{ds1} \\ = {V}_{ccs} + {V}_{gs2} \\ < {V}_{gs2} - {V}_{th2}\end{matrix}$$

Thus, the depletion-type N-channel MOS transistor 12 is operated in a linear region. Therefore, the drain current I_{d2} of the depletion-type N-channel NOS transistor 12 is represented by
I_{d2}=μV₂−(W₂/L₂)−{(V_{gs2}−Vₜₕ₂)−V_{ds2}−(½)−V_{ds2}²}for V_{ccs}<−Vₜₕ₂ (linear region) (9)
The formulae (8) and (9) are combined with the formula (1) to obtain the following formulae (10) and (11):
I_{d2}=(½)−μC₂(W₂/L₂)−(V_{ds1}+Vₜₕ₂)²−(1+λ₂V_{ds2}) for V_{ccs}≧−Vₜₕ₂ (10)
   I_{d2}=μC₂(W₂/L₂)·{−(V_{dS1}+Vₜₕ₂)·V_{ds2}−(½)·V_{ds2}²} for V_{ccs}<−V_{th 2} (11)

Since V_{ds2}=V_{ccs}−V_{ds1}, the formulae (10) and (11) are replaced by:
I_{d2}=(½)·μC₂·(W₂/L₂)·(V_{ds1}−Vₜₕ₂)·{1+λ₂(V_{ccs}−V_{ds1})} for V_{ccs}≧−Vₜₕ₂ (12)
I_{d2}=(½)·μC₂·(W₂/L₂)·{(V_{ds2}+Vₜₕ₂)²·(V_{ccs}−V_{thZ}))²}for V_{ccs}<−Vₜₕ₂ (13)
Thus, the drain-to-source voltage V_{ds1} (P₁) is obtained by solving the formula (4) or (5) and the formula (12) under a condition that I_{d1}=I_{d2}. Also, the drain-to-source voltage V_{ds1} (P₂) is obtained by solving the formula (4) or (5) and the formula (13) under a condition that I_{d1}=I_{d2}.

The current fluctuation of the constant current source apparatus 10 of FIG. 3 caused by the channel length modulation effect will be explained below.

First, assume that:
|Vₜₕ₁|<|Vₜₕ₂| (14)

That is, the absolute value of the threshold voltage Vₜₕ₁ of the depletion-type N-channel MOS transistor 11 is smaller than that of the threshold voltage Vₜₕ₂ of the depletion-type N-channel MOS transistor 12.

Second, assume that:
μC₁−W₁/L₁<<μC₂−W₂/L₂ (15)

That is, the current drive ability of the depletion-type N-channel MOS transistor 11 is much smaller than that of the depletion-type N-channel KOS transistor 12.

Finally, assume that:
λ₁=λ₂=λ (16)

That is, the channel length modulation factor of the depletion-type N-channel MOS transistor 11 is equal to that of the depletion-type N-channel MOS transistor 12.

The conditions defined by the formulae (14), (15) and (16) can easily be realized by a conventional semiconductor manufacturing process.

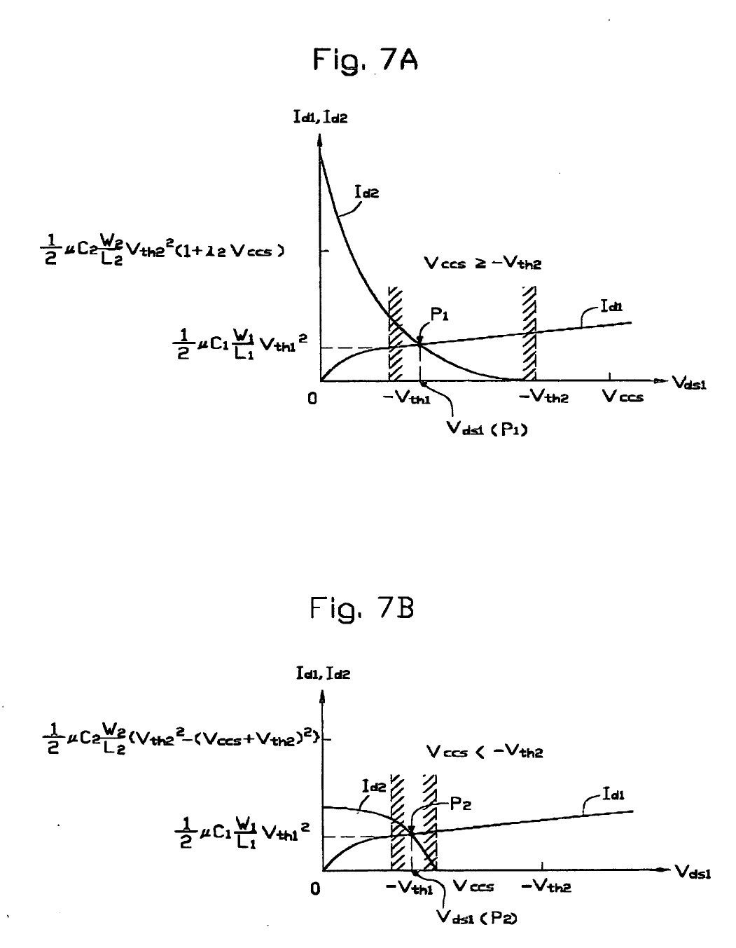

As shown in FIG. 7A, when V_{ccs}≧−Vₜₕ₂, the drain-to-source voltage V_{ds1}(P₁) at the operation point P₁ is between −Vₜₕ₁ and −Vₜₕ₂. Therefore, the channel length modulation effect term λ*V_{ds1} is changed betweenk λ·(−Vₜₕ₁) and λ·(−Vₜₕ₂) so that the fluctuation of the channel length modulation effect term is limited by λ·(Vₜₕ₁−Vₜₕ₂). Thus, the fluctuation of the load current I_{L} by the channel length modulation effect can be suppressed.

In the constant current source apparatus 100 of FIG. 1, note that the channel length modulation effect term λ·V_{ds} is changed between λ·(−Vₜₕ₁) and λ·V_{ccs} so that the fluctuation of the channel length modulation effect term is limited by λ·(Vₜₕ₁+V_{ccs}).

As shown in FIG. 79, when V_{ccs}<−V_{thZ}, the drain-to-source voltage V_{ds1} (P₂) at the operating point P_{Z} is between −Vₜₕ₁ and V_{ccs}. Therefore, the channel length modulation effect term λ·V_{ds1} is changed between λ·(−Vₜₕ₁) and λ·V_{ccs}, so that the fluctuation of the channel length modulation effect term is limited by λ·(Vₜₕ₁−V_{ccs}). Thus, the fluctuation of the load current I_{L} by the channel length modulation effect can be suppressed in the same way as in the constant current source apparatus 100 of FIG. 1. However, even when the voltage V_{ccs} is too highs the depletion-type N-channel MOS transistor 11 can be constructed by a low drain-to-source breakdown voltage N-channel MOS transistor while the depletion-type N-channel MOS transistor 12 can be constructed by a high drain-to-source breakdown voltage N-channel MOS transistor, so that the fluctuation of the load current I_{L} by the channel length modulation effect can be suppressed.

The layout area of the constant current source apparatus of FIG. 3 will be explained below.

Assume that:
|Vₜₕ₁|<<|Vₜₕ₂| (17)
μC₁=μC₂ (18)
W₁=W₂=Wₘᵢₙ (minimum rule) (19)
L₁=L₂=Lₘᵢₙ (minimum rule) (20)
λ₁=λ₂=λ (21)

The conditions defined by the formulae (17), (18), (19), (20) and (21) can also be easily realized by a conventional semiconductor manufacturing process. In this case, operating points P, and P₂ are also shown in FIGS. 7A and 7B.

The load current I_{L} is proportional to the square value of a threshold voltage which is defined by Vₜₕ₁ of the depletion-type N-channel NOS transistor 11 of FIG. 3 or Vₜₕ of the depletion-type N-channel MOS transistor 101 of FIG. 1.

Therefore, in order to make the load current I_{L} in the constant current source apparatus 10 of FIG. 3 equal to the load current I_{L} in the constant current source apparatus 100 of FIG. 1, the ratio of the gate length of the depletion-type N-channel MOS transistor 11 to the depletion-type MOS transistor 101 is Vₜₕ₁²/Vₜₕ² (<1). That is, the gate length of the depletion-type N-channel MOS transistor 11 is Lₛᵢₙ, while the gate length of the depletion-type N-channel MOS transistor 101 is (Vₜₕ²/Vₜₕ₁²) Lₛᵢₙ, so that the gate area of the depletion-type N-channel MOS transistor 11 is Wₘᵢₙ·Lₛᵢₙ, while the gate area of the depletion-type N-channel MOS transistor 101 is (Vₜₕ²/Vₜₕ₁²) Wₛᵢₙ·Lₛᵢₙ. In this case, the total gate area of the depletion-type N-channel MOS transistors 11 and 12 is 2·Wₛᵢₙ·Lₘᵢₙ 101 of FIG. 1 (see: formula (7)). In this case, a low drain-to-source breakdown voltage MOS transistor is used for the depletion-type N-channel MOS transistor 11 of FIG. 3, while a high drain-to-source breakdown voltage MOS transistor is used for the depletion-type N-channel MOS transistor 101 of FIG. 1. As a result,
Vₜₕ₁<Vₜₕ (22)
Since the layout area of a constant current source apparatus is considered to be proportional to the total gate area thereof, if Vₜₕ²/Vₜₕ₁²>2, the layout area can be decreased.

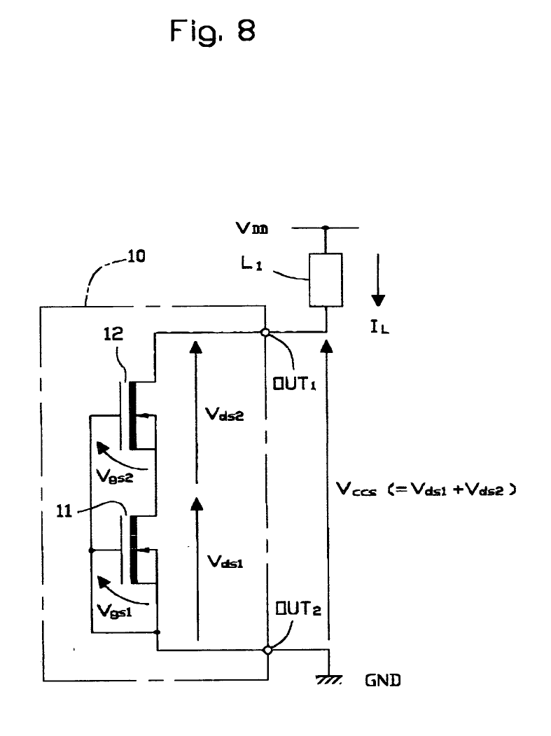

In FIG. 8, which illustrates a modification of the constant current source apparatus 10 of FIG. 3, the back gates of the depletion-type N-channel MOS transistor 11 and 12 are connected to the corresponding sources thereof. That is, in FIG. 3, since the back gates of the depletion-type N-channel MOS transistors 11 and 12 are connected to the source of the depletion-type N-channel MOS transistor 11, the depletion-type N-channel MOS transistors 11 and 12 can be formed within the same P-type well. On the other hand, in FIG. 8, since the back gates of the depletion-type N-channel MOS transistor 11 and 12 are connected to the sources of the depletion-type N-channel MOS transistors 11 and 12, respectively, the depletion-type N-channel MOS transistors 11 and 12 can be formed within different two P-type wells.

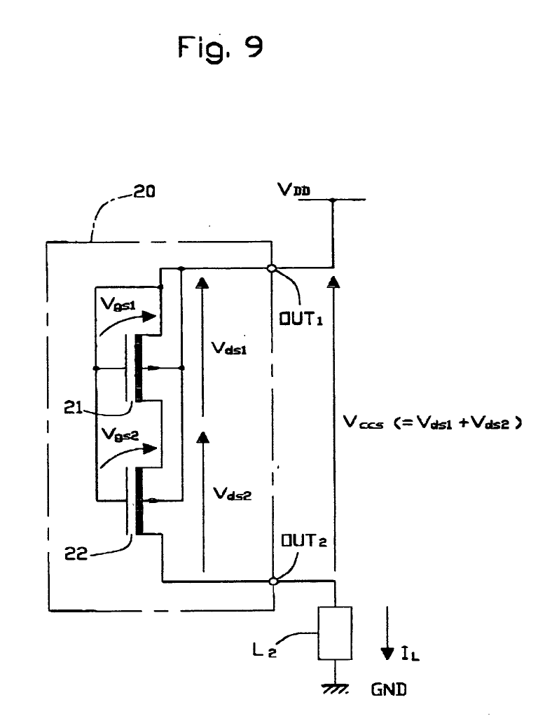

In FIG. 9, which illustrates a second embodiment of the constant current source apparatus according to the present invention, a constant current source apparatus 20 has an output terminal OUT₁ connected to a power supply terminal to which a power supply voltage V_{DD} (>0) is applied and an output terminal OUT_{E} connected to a load L₂ which is further connected to a ground terminal to which the ground voltage GND is applied.

The constant current source apparatus 20 Is constructed by depletion-type MOS P-channel transistors 21 and 22 connected in series between the output terminals OUT₁ and OUT₂. In this case, a source and a gate of the depletion-type P-channel MOS transistor 21 are connected to a source of the depletion-type N-channel MOS transistor 22. Also, back gates of the depletion-type P-channel MOS transistors 21 and 22 are directly connected to the power supply terminal (V_{DD}).

That is, in FIG. 9, the depletion-type N-channel MOS transistors 11 and 12 of FIG. 3 are replaced by the depletion-type P-channel MOS transistors 21 and 22, respectively, The operation of the constant current source apparatus 20 of FIG. 9 is similar to that of the constant current source apparatus 10 of FIG. 3.

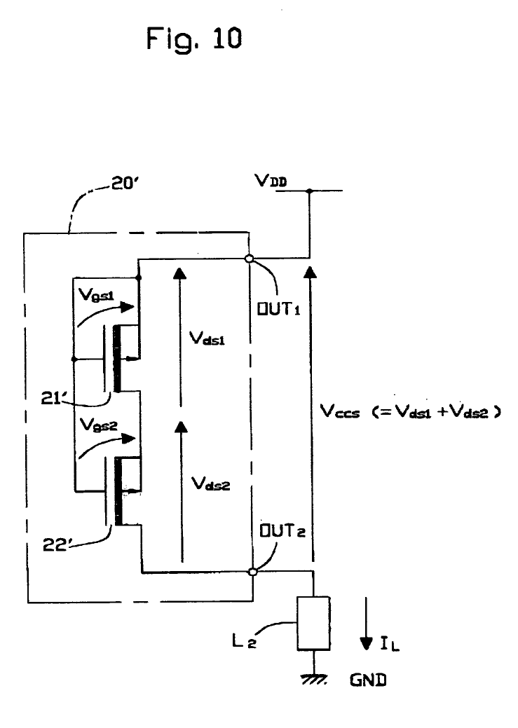

In FIG. 10, which illustrates a modification of the constant current source apparatus 20 of FIG. 9, the back gates of the depletion-type P-channel MOS transistor 21 and 22 are connected the corresponding sources thereof That is, in FIG. 9, since the back gates of the depletion-type P-channel MOS transistors 21 and 22 are connected to the source of the depletion-type P-channel MOS transistor 21, the depletion-type P-channel MOS transistors 21 and 22 can be formed within the same N-type well. On the other hand, in FIG. 10, since the back gates of the depletion-type P-channel MOS transistor 21 and 22 are connected to the sources of the depletion-type P-channel MOS transistors 21 and 22, respectively, the depletion-type P-channel MOS transistors 21 and 22 can be formed within two different N-type wells.

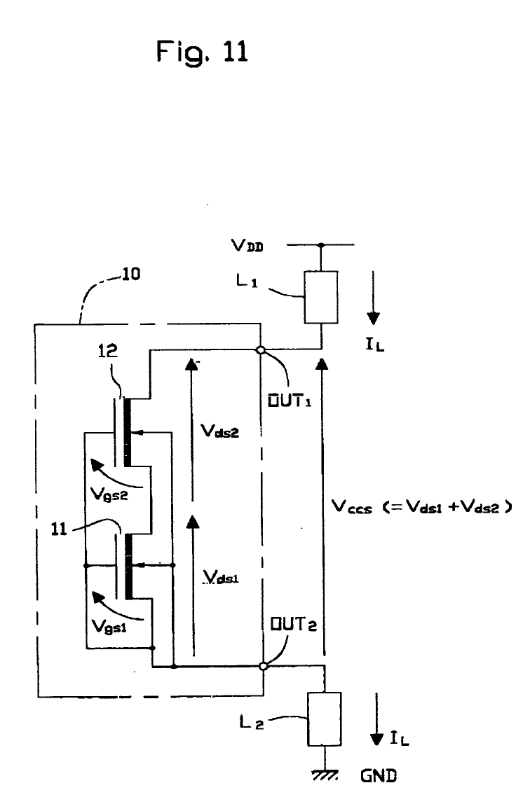

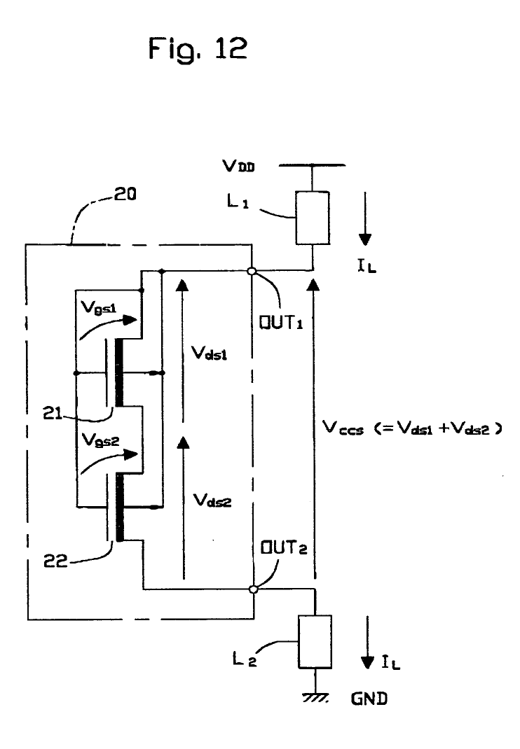

In the above-described embodiments, although the constant current source apparatus 10 or 20 is connected to one load L₁ or L₂, the constant current source apparatus can be connected to two loads L₁ and L₂ as illustrated in FIGS. 11 and 12.

As explained hereinabove, according to the present invention, the current fluctuation by the channel length modulation effect can be suppressed, and also, the layout area can be decreased while the current characteristics can be improved.

1. A constant current source apparatus for supplying a load current to at least one load, comprising:
first and second output terminals, at least one of said first and second output terminals capable of being connected to said load; and
first and second depletion-type MOS transistors connected in series between said first and second output terminals,
a source and a gate of said first depletion-type MOS transistor being connected to a gate of said second depletion-type MOS transistor.

2. The constant current source apparatus as set forth in claim 1, wherein a drain-to-source breakdown voltage of said first depletion-type MOS transistor is larger than an absolute value of a threshold voltage of said second depletion-type MOS transistor.

3. The constant current source apparatus as set forth in claim 1, wherein an absolute value of a threshold voltage of said first depletion-type MOS transistor is smaller than an absolute value of a threshold voltage of said second depletion-type MOS transistor.

4. The constant current apparatus as set forth in claim 1, wherein a drain-to-source breakdown voltage of said first depletion-type is smaller than a drain-to-source breakdown voltage of said second depletion-type MOS transistor.

5. The constant current source apparatus as set forth in claim 1, wherein back gates of said first and second depletion-type MOS transistors are connected to the source of said first depletion-type MOS transistor.

6. The constant current source apparatus as set forth in claim 1, wherein a back gate of said first depletion-type MOS transistor is connected to the source thereof, and a back gate of said second depletion-type MOS transistor is connected to the source thereof.

7. The constant current source apparatus as set forth in claim 1, wherein each of said first and second depletion-type MOS transistors comprises a depletion-type N-channel MOS transistor.

8. The constant current source apparatus as set forth in claim 1, wherein each of said first and second depletion-type MOS transistors comprises a depletion-type P-channel MOS transistor.
